(19) United States
(12) Patent Application Publication
(10) Pub. No.: US 2026/0362916 A1
(43) Pub. Date: Nov. 12, 2026

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Zuchen DU, Wuhan, Hubei (CN); Yanyang LI, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 19/124,883

(22) PCT Filed: Aug. 23, 2024
(86) PCT No.: PCT/CN2024/114148

§ 371 Date: Apr. 27, 2025

(30) Foreign Application Priority Data
Nov. 7, 2023 (CN) 202311483841.8

(51) Int. Cl. H10K 59/131

(52) U.S. Cl. CPC H10K 59/131

(57) ABSTRACT

A display panel is provided by the present application. A first conductive layer includes: multiple first wirings, which are disposed in a display area and extending along a first direction; multiple second wirings extend along the first direction, and alternate with multiple first wirings at intervals; at least one dummy metal pattern is disposed between the first wirings and at least one adjacent second wiring, and the dummy metal pattern is insulated from at least one of the first wirings and the second wirings.

The present application claims the priority to Chinese Application No. 202311483841.8, filed on Nov. 7, 2023, the content of which is incorporated herein by reference in its entirety.

### TECHNICAL FIELD

The present application relates to a technical field of display, and in particular to display panels and display devices.

### BACKGROUND

Organic Light-Emitting Diode (OLED) has been widely used in life. In a production process of the organic light-emitting display panel, a film layer needs to be patterned by a mask. FIG. 1 shows a part of pattern designs of the mask in the related art. A mask pattern in FIG. 1 includes first wiring patterns 101A, second wiring patterns 101B and the first bus pattern 101C. The second wiring patterns 101B and the first wiring patterns 101A are disposed alternately and at intervals. The second wiring patterns 101B are connected to the first bus pattern 101C.

### SUMMARY

The inventor found that while a distance between a second wiring pattern 101B and a first wiring pattern 101A is small, that is, a first distance d1 in FIG. 1 is small, due to an antenna effect, an electrostatic damage is easy to occur between the second wiring pattern 101B and the first wiring pattern 101A. Then as long as a mask after the electrostatic damage is used to manufacture a film layer of a display panel, the display panel is 100% scrapped.

Therefore, in the related art, a mask has a problem of electrostatic damage.

In a first aspect, embodiments of the present application provide a display panel, including a display area and a non-display area surrounding the display area, where the display panel includes a substrate and a first conductive layer disposed on the substrate, and the first conductive layer includes:
first wirings, disposed in the display area and extending along a first direction;
second wirings, extending along the first direction and disposed alternately and at intervals with the first wirings, where a distance between one of the first wirings and at least one of the second wirings adjacent to the first wirings is less than or equal to 10 microns;
a first bus, disposed in the non-display area and extending along a second direction, where the first direction intersects the second direction, the second wirings are connected to a side of the first bus and extend to the display area, and a width of the first bus is greater than or equal to 15 microns; and
at least one dummy metal pattern, disposed between one of the first wirings and at least one of the second wirings adjacent to the one of the first wirings, where the dummy metal pattern is insulated from at least one of the one of the first wirings and the one of the second wiring.

In a second aspect, the embodiments of the present application further provide a display device, including a display panel, and the display panel includes a display area and a non-display area surrounding the display area, where the display panel includes a substrate and a first conductive layer disposed on the substrate, and the first conductive layer includes:
first wirings, disposed in the display area and extending along a first direction;
second wirings, extending along the first direction and disposed alternately and at intervals with the first wirings, where a distance between one of the first wirings and at least one adjacent second wiring is less than or equal to 10 microns;
a first bus, disposed in the non-display area and extending along a second direction, where the first direction intersects the second direction, the second wirings are connected to a side of the first bus and extend to the display area, and a width of the first bus is greater than or equal to 15 microns; and
at least one dummy metal pattern, disposed between one of the first wirings and at least one of the second wirings adjacent to the one of the first wirings, where the dummy metal pattern is insulated from at least one of the one of the first wirings and the one of the second wirings.

### BRIEF DESCRIPTION OF THE DRAWINGS

To more clearly illustrate the embodiments of the present application or related art, accompanying drawings used in the description of the embodiments or the related art are briefly introduced below. It should be noted that, the drawings in the following description only show some embodiments of the present application. For those of ordinary skill in the art, other drawings may also be obtained according to these drawings without creative effort.

FIG. 1 shows a part of pattern designs of a mask in the related art;

FIG. 2 is a top view schematic diagram of a first conductive layer of a display panel provided by Embodiment One of the present application;

FIG. 3 is a schematic diagram of an enlargement of a pattern of a dummy metal pattern on the display panel of FIG. 2.

FIG. 4 is a schematic diagram of part of patterns of a first mask provided by Embodiment One of the present application;

FIG. 5 is a schematic diagram of an enlargement of a connecting wiring pattern of FIG. 4;

FIG. 6 is a cross-section diagram of a position of a first bus on a display panel;

FIG. 7 is a top view schematic diagram of a first conductive layer of a display panel provided by Embodiment Two of the present application;

FIG. 8 is another cross-section diagram of a position of a first bus on a display panel;

FIG. 9 is a schematic diagram of a part of patterns of a first mask provided by Embodiment Two of the present application;

FIG. 10 is a top view schematic diagram of a part of a conductive layer of a display panel provided by Embodiment Three of the present application; and

FIG. 11 is a structural schematic diagram of a display device provided by embodiments of the present application.

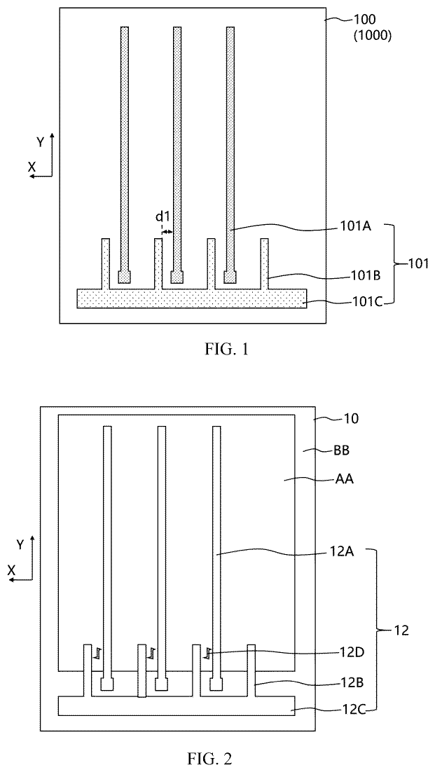

### REFERENCE NUMERALS

10: display panel; AA: display area; BB: non-display area; Y: first direction; X: second direction; 11: substrate; 12: first conductive layer; 13: interlayer insulating layer; 14: second conductive layer, 13A: through hole;
12A: first wiring; 12B: second wiring; 12C: first bus; 12D: dummy metal pattern; 14A: second bus; 12C1: first bus segment; 15A: third bus;
1000: mask group; 100: first mask; 101: first mask pattern; 101A: first wiring pattern; 101B: second wiring pattern; 101C: first bus pattern; 101D: connecting wiring pattern; 101C1: first bus segment pattern;
d1: first distance; k1: first width; F1: first spacing;
100: display device; 20: casing.

### DETAILED DESCRIPTION

The solutions in the embodiments of the present application will be clearly and completely described below with reference to the accompanying drawings. It should be noted that the described embodiments are merely a part of the embodiments of the present application, rather than all the embodiments. Based on the embodiments in the present application, all other embodiments obtained by a person skilled in the art without involving any inventive effort are within the scope of the present application.

In the description of the present application, it should be noted that the orientation or positional relationship indicated by terms such as “on”, “under” and the like, are based on the orientation or positional relationship shown in the drawings, which are merely for convenience of description of the present application and to simplify description, but not indicate or imply that the stated devices or members must have the particular orientation and be constructed and operated in a particular orientation, and thus these can not to be construed as limiting the present application. In addition, the terms “first”, “second” and the like are only used for descriptive purposes and should not be construed as indicating or implying relative importance or implicitly specifying the number of technical features indicated. Therefore, a feature that are limited to “first” and “second” may explicitly or implicitly include one or more of the features. In the description of the present application, “a plurality of” means two or more, unless otherwise expressly specified.

The reference numerals and/or reference letters may be repeated in different embodiments of the present application for the purpose of simplification and clarity, which does not indicate the relationship between the various embodiments and/or arrangements discussed.

Embodiments of the present application provide a display panel, including a display area and a non-display area surrounding the display area, where the display panel includes a substrate and a first conductive layer disposed on the substrate, and the first conductive layer includes:
first wirings, disposed in the display area and extending along a first direction;
second wirings, extending along the first direction and disposed alternately and at intervals with the first wirings, where a distance between one of the first wirings and at least one of the second wirings adjacent to the first wirings is less than or equal to 10 microns;
a first bus, disposed in the non-display area and extending along a second direction, where the first direction intersects the second direction, the second wirings are connected to a side of the first bus and extend to the display area, and a width of the first bus is greater than or equal to 15 microns; and
at least one dummy metal pattern, disposed between one of the first wirings and at least one of the second wirings adjacent to the one of the first wirings, where the dummy metal pattern is insulated from at least one of the one of the first wirings and the one of the second wirings.

In some embodiments, at least one dummy metal pattern connects the first wirings and at least one of the second wirings.

In some embodiments, the dummy metal pattern is connected in a convex shape on the first wirings or the second wirings.

In some embodiments, dummy metal patterns are disposed between the first wirings and the second wirings, and at least one dummy metal pattern is disposed at intervals with the first wirings and the second wirings on two sides of the dummy metal pattern.

In some embodiments, the dummy metal patterns are disposed at intervals between the first wirings and the second wirings provided with the dummy metal patterns.

In some embodiments, the display panel further includes:
a second conductive layer, disposed on the substrate, and including a second bus extending along a second direction; and
an interlayer insulating layer, disposed between the first conductive layer and the second conductive layer, and including through holes;
where, the second bus is at least partially overlapped with the first bus in a thickness direction of the display panel, and the second bus is connected to the first bus through the through holes; or the second bus is electrically connected to the first bus through bridge electrodes passing through the through holes.

In some embodiments, the first bus includes first bus segments disposed at interval, and the first bus segments are connected to at least one of the second wirings.

The first bus segments are electrically connected to the second bus through at least one of the through holes.

In some embodiments, the display panel includes thin film transistors arranged in an array, and each of the thin film transistors includes a source and a drain.

In addition, at least one of the first conductive layer and the second conductive layer further includes the source and the drain.

In some embodiments, the first conductive layer or the second conductive layer further includes a third bus.

On a plane of the display panel, the third bus is disposed at a side of the first bus away from the display area, and the third bus is electrically connected to the first wirings.

In some embodiments, the first wirings are reset signal lines, the second wirings and the first bus are VDD signal wirings.

Embodiments of the present application provide a display panel, including a display area and a non-display area surrounding the display area. The display panel includes a substrate and a first conductive layer disposed on the substrate. The first conductive layer includes: first wirings, disposed in the display area and extending along a first direction; second wirings, extending along the first direction and disposed alternately and at intervals with the first wirings, where a distance between one of the first wirings and at least one of the second wirings is less than or equal to 10 microns; a first bus, disposed in the non-display area and extending along a second direction, where the first direction intersects the second direction, the second wirings are connected to a side of the first bus and extend to the display area, and a width of the first bus is greater than or equal to 15 microns; and at least one dummy metal pattern, disposed between one of the first wirings and at least one of the second wirings adjacent to the one of the first wirings, where the dummy metal pattern is insulated from at least one of the one of the first wirings and the one of the second wirings. In the present application, the display panel is made of a mask that may solve a problem of electrostatic damage in the mask. In an improved first mask, a static electricity is released by arrangement a connecting wiring pattern between the first wiring pattern and the second wiring pattern, so as to avoid the problem of electrostatic damage caused by an antenna effect due to a too close distance between the first wiring pattern and the second wiring pattern, and solve the problem that a first mask is easy to be damaged. An improved mask group or the first mask may avoid a decrease of a yield of the display panel. In addition, due to a small width of the connecting wiring pattern, while the first conductive layer is formed on the substrate, a pattern part corresponding to the connecting wiring pattern on the first conductive layer is etched off, and a remaining conductive layer forms a dummy metal pattern. The dummy metal pattern is insulated from at least one of the first wirings and the second wirings, thus ensuring design requirements of the display panel.

The present application provides a display panel, including a display area and a non-display area surrounding the display area. The display panel includes a substrate and a first conductive layer disposed on the substrate. The first conductive layer includes: first wirings, disposed in the display area and extending along a first direction; second wirings, extending along the first direction and disposed alternately and at intervals with the first wirings, where a distance between one of the first wirings and at least one of the second wirings adjacent to the first wirings is less than or equal to 10 microns; a first bus, disposed in the non-display area and extending along a second direction, where the first direction intersects the second direction, the second wirings are connected to a side of the first bus and extend to the display area, and a width of the first bus is greater than or equal to 15 microns; and at least one dummy metal pattern, disposed between one of the first wirings and at least one of the second wirings adjacent to the one of the first wirings, where the dummy metal pattern is insulated from at least one of the one of the first wirings and the one of the second wirings. The following are described in detail. It should be noted that the description order of the following embodiments is not used as a limitation on the preferred order of embodiments.

### Embodiment One

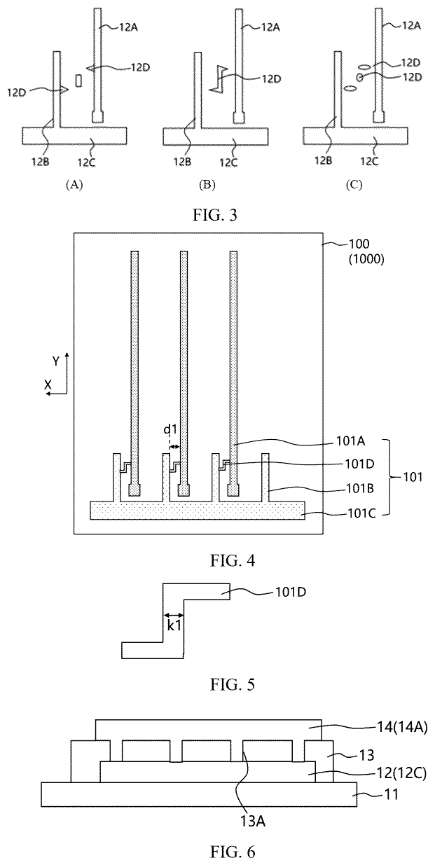

Referring to FIG. 2 to FIG. 6, FIG. 2 is a top view schematic diagram of a first conductive layer of a display panel provided by Embodiment One of the present application; and FIG. 3 is a schematic diagram of an enlargement of a pattern of a dummy metal pattern on the display panel of FIG. 2. FIG. 3(a), FIG. 3(b) and FIG. 3(c) respectively illustrate patterns of dummy metal patterns on the display panel in different situations. FIG. 4 is a schematic diagram of part of patterns of a first mask 100 provided by Embodiment One of the present application; FIG. 5 is a schematic diagram of an enlargement of a connecting wiring pattern of FIG. 4; and FIG. 6 is a cross-section diagram at a position of a first bus on a display panel.

The present application provides a display panel 10, which includes a display area AA and a non-display area BB surrounding the display area AA. The display panel 10 includes a substrate 11 and a first conductive layer 12 disposed on the substrate 11. The first conductive layer 12 includes first wirings 12A, second wirings 12B, a first bus 12C, and at least one dummy metal pattern 12D. The first wirings 12A are disposed in the display area AA and extending along the first direction Y. The second wirings 12B extend along the first direction Y, and alternate with the first wirings 12A and are disposed at intervals. A distance between one of the first wirings 12A and at least one of the second wirings 12B adjacent to the first wirings is less than or equal to 10 microns. The first bus 12C is disposed in the non-display area BB and extends along the second direction X. The first direction Y intersects with the second direction X. The second wirings 12B are connected to a side of the first bus 12C and extend to the display area AA. A width of the first bus 12C is greater than or equal to 15 microns. At least one dummy metal pattern 12D is disposed between one of the first wirings 12A and at least one of the second wiring 12B adjacent to the one of the first wirings, and the dummy metal pattern 12D is insulated from at least one of the first wirings 12A and the second wirings 12B.

In addition, the first bus 12C may be connected to an external driver chip or an external power supply to provide electrical signals for the second wirings 12B.

In an embodiment, the first direction Y and the second direction X are perpendicular to each other.

In an embodiment, the first direction Y is perpendicular to a boundary between the display area AA and the non-display area BB, and the second direction X is parallel to the boundary between the display area AA and the non-display area BB.

In addition, the display panel 10 provided in the present application is manufactured by a mask group 1000 which solves the problem of electrostatic damage of a mask, and more specifically, the display panel 10 is manufactured by the first mask 100 in the mask group 1000.

As shown in FIG. 3, the mask group 1000 includes at least a first mask 100, the first mask 100 includes a first mask pattern 101 for forming a first conductive layer 12 on a substrate 11, and the first mask pattern 101 includes first wiring patterns 101A, second wiring patterns 101B, a first bus pattern 101C, and at least one connecting wiring pattern 101D. The first wiring patterns 101A, the second wiring patterns 101B, the first bus pattern 101C, and the connecting wiring pattern 101D are used to form first wirings 12A, second wirings 12B, a first bus 12C, and at least one dummy metal pattern 12D, respectively.

In addition, an arrangement and an extension direction of the first wiring pattern 101A, the second wiring patterns 101B, and the first bus pattern 101C in the first mask 100 or the first mask pattern 101 is the same as an arrangement and an extension direction of the first wirings 12A, the second wirings 12B, and the first bus 12C in the display panel 10 (the first conductive layer 12), and are not repeated here.

In addition, a distance between one of the first wiring patterns 101A and at least one of the second wiring patterns 101B adjacent to the first wiring patterns is less than or equal to 10 microns, and the connecting wiring pattern 101D is connected between adjacent one of the first wiring patterns 101A and one of the second wiring patterns 101B.

In an embodiment, a width of a pattern of the connecting wiring pattern 101D and a width of the dummy metal pattern 12D are less than or equal to 0.6 microns.

Referring to FIG. 2 and FIG. 4, a pattern shape of the first conductive layer 12 patterned by the first mask 100 on the substrate 11 in FIG. 4 is shown in FIG. 2, and an adopted light resistance is positive. It should be noted that the first mask pattern 101 on the first mask 100 is roughly similar to or the same as a pattern of the first conductive layer 12 on the substrate 11. The first mask pattern 101 on the first mask 100 is an opaque area, and an area except the first mask pattern 101 is a transparent area. It should be noted that in order to facilitate the nature of the application, FIG. 4 only shows part of the patterns of the first mask pattern 101. The first mask pattern 101 may further include other mask patterns.

In addition, a width of the first bus pattern 101C is greater than or equal to 15 microns, that is, an area of the first bus pattern 101C is large, which makes it easy to accumulate a large amount of electrostatic charges on the first mask pattern 101.

In addition, a distance between one of the first wiring patterns 101A and at least one of the second wiring patterns 101B adjacent to the first wiring patterns is less than or equal to 10 microns, so that an antenna effect exists between the first wiring patterns 101A and the second wiring patterns 101B. The electrostatic damage is easy to occur between the second wiring patterns 101B and the first wiring patterns 101A. Then as long as a mask after the electrostatic damage is used to manufacture a film layers of a display panel, the display panel is 100% scrapped.

In addition, the connecting wiring pattern 101D is connected between one of the first wiring patterns 101A and one of the second wiring patterns 101B adjacent to the first wiring patterns 101A, that is, one of the first wiring patterns 101A is connected to at least one of the second wiring patterns 101B by the connecting wiring pattern 101D, or one second wiring pattern 101B is connected to at least one of the first wiring patterns 101A by the connecting wiring pattern 101D.

In addition, electrostatic charges are released between the first wiring patterns 101A and the second wiring patterns 101B by the connecting wiring pattern 101D. In addition, in an embodiment, a width of the connecting wiring pattern 101D in a direction perpendicular to an extension direction of the connecting wiring pattern 101D is less than or equal to 0.6 microns, that is, a first width k1 in FIG. 5 is less than or equal to 0.6 microns. Since a width of the connecting wiring pattern 101D is very small, and while the first conductive layer 12 is formed on the substrate 11, a pattern corresponding to the connecting wiring pattern 101D on the first conductive layer 12 is partially etched and only some residual conductive layer materials are retained (while a width of a thin wiring on the first conductive layer 12 is less than or equal to 0.6 microns, due to a diffraction of light and an influence of a process, a light resistance above the thin wiring is less, and the thin wiring would be etched in a subsequent etching process, and only part would be left on an actual display panel 10 or substrate 11). The residual conductive layer forms a dummy metal pattern 12D, and the dummy metal pattern 12D is insulated from at least one of the first wirings 12A and the second wirings 12B. Therefore, design requirements of a display panel 10 are guaranteed.

In some embodiments, as shown in FIG. 3(a), at least one dummy metal pattern 12D connects the first wirings 12A or the second wirings 12B.

In addition, a residual metal formed by the connecting wiring pattern 101D may be at least one dummy metal pattern 12D to connect the first wirings 12A, or/and at least one dummy metal pattern 12D to connect the second wirings 12B.

In some embodiments, as shown in FIG. 3(a), the dummy metal pattern 12D is connected to the first wirings 12A or the second wirings 12B in a convex shape.

In addition, an etched shape of the residual metal formed by the connecting wiring pattern 101D is easy to form a convex shape connected to the first wirings 12A or/and the second wirings 12B, and the convex shape may be tip convex and triangular convex.

In some embodiments, as shown in FIG. 3(b), at least one dummy metal pattern 12D are disposed, at intervals with the first wirings 12A and the second wirings 12B on two sides of the dummy metal pattern 12D, between the first wirings 12A and the second wirings 12B provided with dummy metal patterns 12D.

In some embodiments, as shown in FIG. 3(c), the dummy metal patterns 12D are disposed at intervals between the first wirings 12A and the second wirings 12B provided with the dummy metal patterns 12D.

It should be noted that FIG. 3(a), FIG. 3(b) and FIG. 3(c) respectively indicate several patterns of the dummy metal pattern 12D, but patterns of the dummy metal pattern 12D are not limited to thereto, as long as the dummy metal pattern 12D is insulated from at least one of the first wirings 12A and the second wirings 12B.

In some embodiments, as shown in FIG. 6, the display panel 10 further includes a second conductive layer 14 and an interlayer insulating layer 13. The second conductive layer 14 is disposed on the substrate 11, and the second conductive layer 14 includes a second bus 14A extending along a second direction X. The interlayer insulating layer 13 is disposed between the first conductive layer 12 and the second conductive layer 14, and the interlayer insulating layer 13 includes through holes 13A. In addition, the second bus 14A is at least partially overlapped with the first bus 12C in a thickness direction of the display panel 10, and the second bus 14A is connected to the first bus 12C through the through holes 13A; or the second bus 14A is electrically connected to the first bus through the through holes 13A through a bridging electrode.

In addition, in the thickness direction of the display panel 10, the first bus 12C and the second bus 14A are electrically connected to provide the same electrical signal to the second wirings 12B, which may reduce a resistance of a wiring providing the same electrical signal.

In addition, while the bridging electrode is part of the first bus 12C or the second bus 14A, the second bus 14A is at least partially overlapped with the first bus 12C in the thickness direction of the display panel 10, and the second bus 14A is directly connected to the first bus 12C through the through holes 13A.

In addition, while the bridging electrode is not part of the first bus 12C or the second bus 14A, the second bus 14A may not be overlapped with the first bus 12C in the thickness direction of the display panel 10. One end of the bridging electrode is connected to the first bus 12C, and another end of the bridging electrode is connected to the second bus 14A. The bridging electrode may be disposed on the same layer or different layers with the first bus 12C or the second bus 14A.

### Embodiment Two

The features of the display panel 10 of this embodiment may be implemented separately, and the characteristics of the display panel 10 of this embodiment may also be implemented together with the characteristics of the display panel 10 of the embodiments described above.

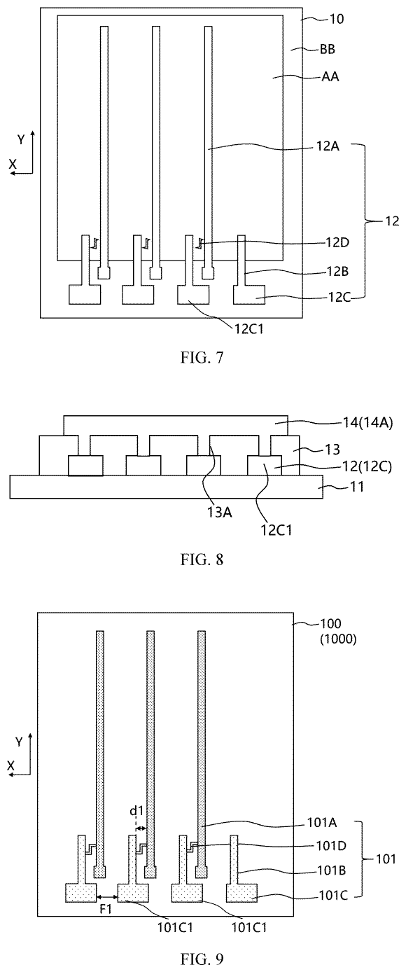

Referring to FIG. 7 to FIG. 9, FIG. 7 is a top view diagram of a first conductive layer of a display panel provided by Embodiment Two of the present application; FIG. 8 is another cross-section diagram of a position of a first bus on a display panel; and FIG. 9 is a schematic diagram of part of patterns of a first mask provided by Embodiment Two of the present application.

In some embodiments, as shown in FIG. 7 and FIG. 8, the first bus 12C includes first bus segments 12C1 disposed at intervals, and the first bus segments 12C1 connect at least one of the second wirings 12B, and the first bus segments 12C1 are electrically connected to the second bus 14A through at least one of the through holes 13A.

The display panel 10 in FIG. 7 and FIG. 8 may be manufactured from the first mask 100 shown in FIG. 9.

As shown in FIG. 9, the first bus pattern 101C includes first bus segment patterns 101C1 disposed at intervals. The first bus segment patterns 101C1 connect at least one of the second wiring patterns 101B, and the first bus segment patterns 101C1 are used to form the first bus segments 12C1.

In addition, the first bus pattern 101C includes the first bus segment patterns 101C1 disposed at intervals. A larger area of the first bus patterns 101C is broken into small blocks to avoid larger charges accumulating in the larger area or the first bus patterns 101C as a whole and concentrating on part of the second wiring patterns 101B, avoiding an accumulation of larger electrostatic charges, thereby avoiding electrostatic damage to the second wirings 12B and the first wirings 12A.

In some embodiments, a distance between adjacent first bus segment patterns 101C1 is less than or equal to 0.6 microns, that is, a first spacing F1 shown in FIG. 9 is less than or equal to 0.6 microns. Since the distance between the adjacent first bus segment patterns 101C1 is very small, while the distance between the adjacent first bus segment patterns 101C1 is less than or equal to 0.6 um, due to an influence of light diffraction and process, a light resistance exists on a spacing between the first bus segment patterns 101C1, and a corresponding distance cannot be made in a subsequent etching process. The distance between the first bus segments 12C1 cannot be made on the actual display panel 10 or substrate 11, so that the first bus 12C becomes a whole wiring, so that the first bus segments 12C1 are connected and conductive, and the first bus 12C of a shape shown in FIG. 2 may be formed. It meets the design requirements of the first bus 12C on the display panel 10.

In some embodiments, the distance between the adjacent first bus section patterns 101C1 is greater than 0.6 microns, that is, while the first spacing F1 in FIG. 9 is greater than 0.6 microns, and the distance between the adjacent first bus section patterns 101C1 is greater than 0.6 um, no light resistance exists on the spacing between the first bus section patterns 101C1, or the light resistance on the spacing between the first bus section pattern 101C1 is blocked. In a subsequent etching process, the spacing between the adjacent first bus segment patterns 101C1 is formed or the adjacent first bus segment patterns 101C1 are disconnected. As such, the distance between the two adjacent first bus segments 12C1 is also greater than 0.6 microns.

In order to enable the first bus 12C to provide electrical signals to the second wirings 12B, as shown in FIG. 8, the second conductive layer 14 or the second bus 14A may be disposed on the display panel 10.

### Embodiment Three

This embodiment is a further introduction to the display panel 10 of Embodiment One, the display panel 10 of Embodiment Two, and the display panel 10 of combined with Embodiment One and Embodiment Two.

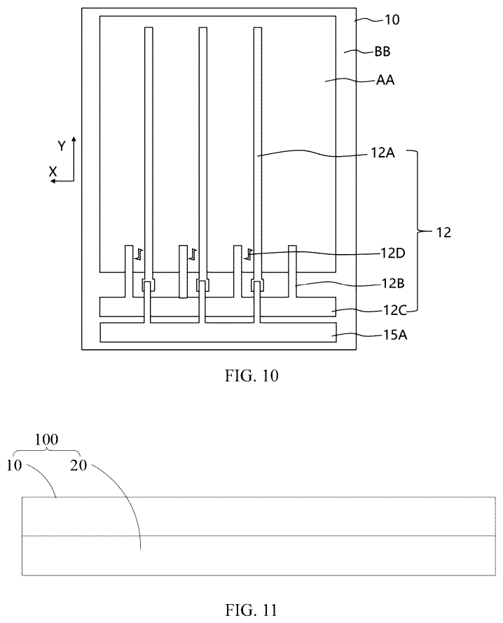

Referring to FIG. 10, FIG. 10 is a top view schematic diagram of a partial conductive layer of a display panel provided by Embodiment Three of the present application.

In some embodiments, the display panel 10 includes thin film transistors arranged in an array, and each of the thin film transistors includes source and drain; where, at least one of the first conductive layer 12 and the second conductive layer 14 further includes the source and drain.

In addition, the source and the drain are disposed/manufactured in the same layer with the first wiring 12A or the second bus 14A, which may reduce the manufacturing process of the display panel 10.

In some embodiments, as shown in FIG. 10, the display panel further includes a third bus 15A. On a plane of the display panel 10, the third bus 15A is disposed at a side of the first bus 12C away from the display area AA, and the third bus 15A is electrically connected to the first wirings 12A.

In addition, the third bus 15A may be connected to an external driver chip or an external power supply to provide electrical signals for multiple first wiring 12A.

In some embodiments, as shown in FIG. 10, the first wirings 12A and the third bus 15A are reset signal lines, and the second wirings 12B, the first bus 12C and the second bus 14A are VDD signal wirings.

In addition, the display panel 10 may be an organic light-emitting display panel 10 (OLED). The display panel 10 includes a light-emitting member and a pixel circuit for driving the light-emitting member. The pixel circuit may be a 7T1C drive circuit or a 7T2C drive circuit. The pixel circuit includes a reset thin film transistor. Each of the reset signal lines may provide a reset signal for the reset thin film transistor or the pixel circuit. The VDD signal wiring may provide a VDD power supply signal for the pixel circuit.

The embodiments of the present application further provide a display device, as shown in FIG. 11. FIG. 11 is a structural diagram of a display device provided by an embodiment of the present application. The display device 100 includes a display panel 10 and a casing 20. The display panel 10 is disposed on the casing 20, and the display panel 10 may provide the display panel 10 for any of above embodiments. The display device 100 may have the same technical effect as the display panel 10 provided by any one of the above embodiments, which would not be repeated here.

In summary, although the present application is disclosed as above with preferred embodiments, the above preferred embodiments are not used to limit the present application. The skilled in the art may make various changes and modifications without departing from the spirit and scope of the present application. Therefore, the scope of protection of the present application is based on the scope defined by the claims.

1. A display panel, comprising a display area and a non-display area surrounding the display area, wherein the display panel comprises a substrate and a first conductive layer disposed on the substrate, and the first conductive layer comprises:
a plurality of first wirings, disposed in the display area and extending along a first direction;
a plurality of second wirings, extending along the first direction and disposed alternately and at intervals with the first wirings, wherein a distance between one of the first wirings and at least one of the second wirings adjacent to the first wirings is less than or equal to 10 microns;
a first bus, disposed in the non-display area and extending along a second direction, wherein the first direction intersects the second direction, the plurality of second wirings are connected to a side of the first bus and extend to the display area, and a width of the first bus is greater than or equal to 15 microns; and
at least one dummy metal pattern, disposed between one of the first wirings and at least one of the second wirings adjacent to the one of the first wirings, wherein the dummy metal pattern is insulated from at least one of the one of the first wirings and the one of the second wirings.

2. The display panel of claim 1, wherein the at least one dummy metal pattern connects the one of the first wirings or the one of the second wirings.

3. The display panel of claim 2, wherein the dummy metal pattern is connected in a convex shape to the one of the first wirings or the one of the second wirings.

4. The display panel of claim 1, wherein the dummy metal pattern is disposed between the one of the first wirings and the one of the second wirings, and the at least one dummy metal pattern is disposed at intervals with the one of the first wirings and the one of the second wirings on two sides of the dummy metal pattern.

5. The display panel of claim 1, wherein a plurality of dummy metal patterns are disposed at intervals between the first wirings and the second wirings provided with the dummy metal patterns.

6. The display panel of claim 1, further comprising:
a second conductive layer, disposed on the substrate and comprising a second bus extending along a second direction; and
an interlayer insulating layer, disposed between the first conductive layer and the second conductive layer and comprising a plurality of through holes;
wherein, the second bus is at least partially overlapped with the first bus in a thickness direction of the display panel, and the second bus is connected to the first bus through the through holes; or the second bus is electrically connected to the first bus through bridge electrodes passing through the through holes.

7. The display panel of claim 6, wherein the first bus comprises a plurality of first bus segments disposed at interval, and the first bus segments are connected to at least one of the second wirings; and
the first bus segments are electrically connected to the second bus through at least one of the through holes.

8. The display panel of claim 6, wherein the display panel comprises a plurality of thin film transistors arranged in an array, and each of the thin film transistors comprises a source and a drain;
wherein at least one of the first conductive layer and the second conductive layer further comprises the source and the drain.

9. The display panel of claim 6, further comprising a third bus;
wherein on a plane of the display panel, the third bus is disposed at a side of the first bus away from the display area, and the third bus is electrically connected to the plurality of first wirings.

10. The display panel of claim 1, wherein the first wirings are reset signal lines, and the second wirings and the first bus are VDD signal wirings.

11. A display device, comprising a display panel, wherein the display panel comprises a display area and a non-display area surrounding the display area, wherein the display panel comprises a substrate and a first conductive layer disposed on the substrate, and the first conductive layer comprises:
a plurality of plurality of first wirings, disposed in the display area and extending along a first direction;
a plurality of second wirings, extending along the first direction and disposed alternately and at intervals with the first wirings, wherein a distance between one of the first wirings and at least one of the second wirings adjacent to the first wirings is less than or equal to 10 microns;
a first bus, disposed in the non-display area and extending along a second direction, wherein the first direction intersects the second direction, the plurality of second wirings are connected to a side of the first bus and extend to the display area, and a width of the first bus is greater than or equal to 15 microns; and
at least one dummy metal pattern, disposed between one of the first wirings and at least one of the second wirings adjacent to the one of the first wirings, wherein the dummy metal pattern is insulated from at least one of the one of the first wirings and the one of the second wirings.

12. The display device of claim 11, wherein the at least one dummy metal pattern connects the one of the first wirings or the one of the second wirings.

13. The display device of claim 12, wherein the dummy metal pattern is connected in a convex shape to the one of the first wirings or the one of the second wirings.

14. The display device of claim 11, wherein the dummy metal pattern is disposed between the one of the first wirings and the one of the second wirings, and the at least one dummy metal pattern is disposed at intervals with one of the first wirings and the one of the second wirings on two sides of the dummy metal pattern.

15. The display device of claim 11, wherein the dummy metal pattern is disposed at intervals between the first wirings and the second wirings provided with the dummy metal patterns.

16. The display device of claim 11, wherein the display panel further comprises:
a second conductive layer, disposed on the substrate and comprising a second bus extending along a second direction; and
an interlayer insulating layer, disposed between the first conductive layer and the second conductive layer and comprising a plurality of through holes;
wherein, the second bus is at least partially overlapped with the first bus in a thickness direction of the display panel, and the second bus is connected to the first bus through the through holes; or the second bus is electrically connected to the first bus through bridge electrodes passing through the through holes.

17. The display device of claim 16, wherein the first bus comprises a plurality of first bus segments disposed at interval, and the first bus segments are connected to at least one of the second wirings; and
the first bus segments are electrically connected to the second bus through at least one of the through holes.

18. The display device of claim 16, wherein the display panel comprises a plurality of thin film transistors arranged in an array, and each of the thin film transistors comprises a source and a drain;
wherein at least one of the first conductive layer and the second conductive layer further comprises the source and the drain.

19. The display device of claim 16, wherein the display panel further comprises a third bus;
wherein on a plane of the display panel, the third bus is disposed at a side of the first bus away from the display area, and the third bus is electrically connected to the plurality of first wirings.

20. The display device of claim 11, wherein the first wirings are reset signal lines, and the second wirings and the first bus are VDD signal wirings.
